(19) United States
(12) Patent Application Publication
(10) Pub. No.: US 2018/0107539 A1
(43) Pub. Date: Apr. 19, 2018

(54) SEMICONDUCTOR MEMORY DEVICE

(71) Applicant: SK hynix Inc., Gyeonggi-do (KR)

(72) Inventor: Hyung-Sik WON, Chungcheongbuk-do (KR)

(21) Appl. No.: 15/603,547

(22) Filed: May 24, 2017

(30) Foreign Application Priority Data
Oct. 18, 2016 (KR) 10-2016-0135021

(51) Int. Cl. G06F 11/10; G11C 29/52; G11C 11/4091; G11C 11/408

(52) U.S. Cl. CPC G06F 11/1068; G11C 11/408; G11C 11/4091; G11C 29/52

(57) ABSTRACT

A semiconductor memory device includes: a normal data storing region suitable for storing normal cell data and outputting N normal cell data to a first local data line in response to one of a plurality of column selection signals, and a parity storing region suitable for storing parity bits and outputting M parity bits to a second local data line in response to at least one of the plurality of the column selection signals, N and M being positive integers, wherein, when M is smaller than N, the parity storing region outputs the M parity bits in response to one of the plurality of the column selection signals, and when M is greater than N, the parity storing region outputs the M parity bits in response to at least two column selection signals that are enabled simultaneously among the plurality of the column selection signals.

### CROSS-REFERENCE TO RELATED APPLICATIONS

The present application claims priority of Korean Patent Application No. 10-2016-0135021, filed on Oct. 18, 2016, which is incorporated herein by reference in its entirety.

### BACKGROUND

### 1. Field

Exemplary embodiments of the present invention relate to a semiconductor technology, and more particularly, to a semiconductor memory device performing an error correction code (ECC) operation.

### 2. Description of the Related Art

The memory capacity of a semiconductor memory device is increasing as fabrication process technologies progress. As micronization technology advances, the number of defective memory cells increases. The increase in the number of defective memory cells not only decrease the production yield of a semiconductor memory device but also makes it hard to secure memory capacity. Therefore, developing new methods for improving the yield of a semiconductor memory device would be highly desirable.

### SUMMARY

Various embodiments of the present invention are directed to a semiconductor memory device capable of performing an error correction code (ECC) operation by using parity bits that are stored in a memory array region.

In accordance with an embodiment of the present invention, a semiconductor memory device includes: a normal data storing region suitable for storing normal cell data and outputting N normal cell data to a first local data line in response to one of a plurality of column selection signals; and a parity storing region suitable for storing parity bits and outputting M parity bits to a second local data line in response to at least one of the plurality of the column selection signals, N and M being positive integers, wherein, when M is smaller than N, the parity storing region outputs the M parity bits in response to one of the plurality of the column selection signals, and when M is greater than N, the parity storing region outputs the M parity bits in response to at least two column selection signals that are enabled simultaneously among the plurality of the column selection signals.

In accordance with another embodiment of the present invention, a semiconductor memory device includes: a normal data storing region suitable for storing normal cell data and outputting N normal cell data to first segment data lines in response to one of a plurality of column selection signals, N being a positive integer; and a parity storing region suitable for storing parity bits and outputting M parity bits to second segment data lines in response to one of the plurality of the column selection signals, M being a positive integer smaller than N, wherein the number of the second segment data lines is smaller than the number of the first segment data lines.

In accordance with yet another embodiment of the present invention, a semiconductor memory device includes: a normal data storing region suitable for storing normal cell data and outputting N normal cell data to a first local data line in response to one of a plurality of column selection signals, N being a positive integer; and a parity storing region suitable for storing parity bits and outputting (N+K) parity bits to a second local data line in response to two column selection signals that are simultaneously enabled among the plurality of the column selection signals, K being a positive integer smaller than N.

### BRIEF DESCRIPTION OF THE DRAWINGS

The above and other features and advantages of the present invention will become more apparent to those skilled in the art to which the present invention pertains by the following detailed description with reference to the attached drawings in which:

FIG. 1 shows a memory bank architecture of a case where a burst length of a segment data is equal to the number of parity bits.

FIG. 2 is a schematic diagram illustrating a coupling between a segment data line and a cell matrix of a parity storing region shown in FIG. 1.

FIG. 3 is a schematic diagram illustrating a coupling between a bit line and a segment data line according to a column selection signal shown in FIG. 2.

FIG. 4 is a table showing the number of parity bits that are required for an error correction code (ECC) operation according to the number of bits of an output data.

FIG. 5 is a memory bank architecture in accordance with a first embodiment of the present invention.

FIG. 6 illustrates a coupling between a segment data line and a cell matrix of a parity storing region shown in FIG. 5.

FIG. 7 is a memory bank architecture in accordance with a second embodiment of the present invention.

FIG. 8 illustrates a coupling between a segment data line and a cell matrix of a parity storing region shown in FIG. 7.

FIG. 9 is a memory bank architecture in accordance with a third embodiment of the present invention.

FIG. 10 is a timing diagram illustrating a column selection signal shown in FIG. 9.

FIGS. 11A and 11B illustrate a coupling between a segment data line and a cell matrix of a parity storing region shown in FIG. 9.

FIG. 12 is a memory bank architecture in accordance with a fourth embodiment of the present invention.

FIG. 13 is a timing diagram illustrating a column selection signal shown in FIG. 12.

FIGS. 14A and 14B illustrate a coupling between a segment data line and a cell matrix of a parity storing region shown in FIG. 12.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The memory capacity of a semiconductor memory device, e.g., a dynamic random access memory (DRAM) device, is increasing due to the advancement of fabrication technology. However, as micronization technology advances, the number of defective memory cells is increasing as well.

To secure production yield, a repair operation for replacing a defective memory cell with a redundant memory cell may be performed. However, it may be impossible to secure a sufficient amount of yield just with a repair operation. Thus, a method for saving error bits by applying both of a repair operation and an error correction code (ECC) operation to the inside of a DRAM device is required.

The ECC operation may provide an ECC function of detecting errors that may occur in the course of registering a data and self-correcting the errors. To provide data integrity, the DRAM device may adopt an ECC circuit. The ECC circuit may perform an ECC operation by using the parity bits in the process of detecting and correcting an error. Therefore, it is necessary to secure an additional memory area for storing the parity bits in the DRAM device. Recently, a scheme of allocating a portion of the memory array region of a DRAM device as a region for storing parity bits is introduced.

Meanwhile, the minimal unit of a data (which is referred to as ‘a segment data’, hereafter) that is outputted from a bit line sense amplifier to the segment data line in the memory array region of the DRAM device may be 8IO/1CYi. In other words, 8 bit line pairs are selected for one cell matrix in response to one column selection signal CYi and thus 8 data are obtained through the segment data line. Therefore, input and output of a segment data having a burst length corresponding to a multiple of 8 at a time based on the 8IO/1CYi may be generally performed.

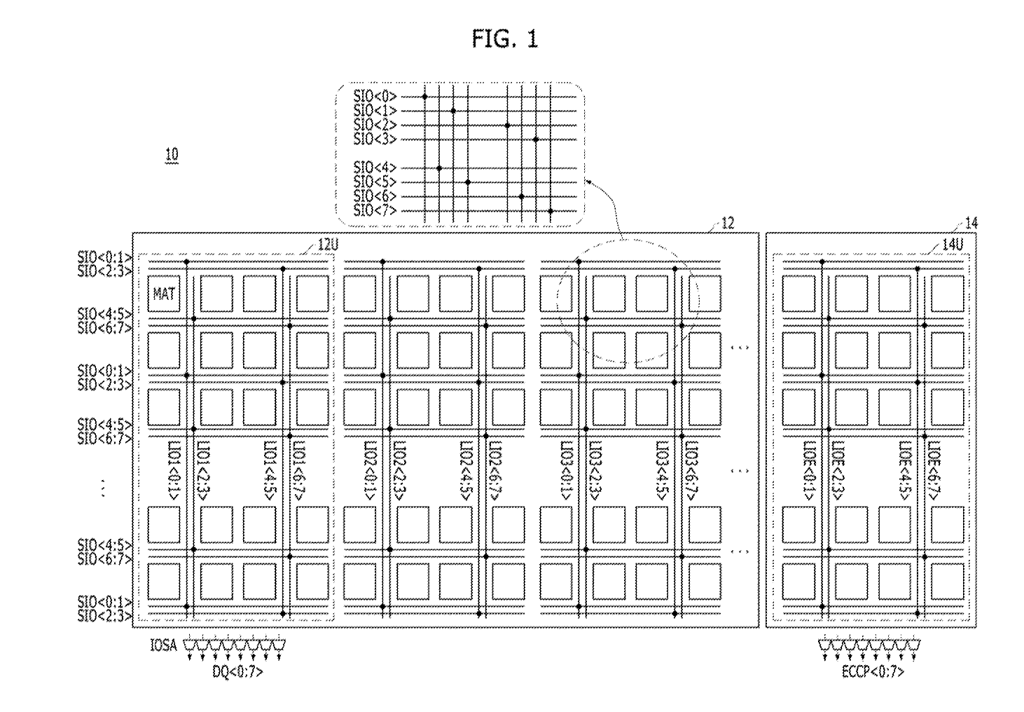

FIG. 1 shows a memory bank architecture of a case where a burst length of a segment data is equal to the number of parity bits.

Referring to FIG. 1, a memory bank 10 may include a normal data storing region 12 for storing normal cell data and a parity storing region 14 for storing parity bits. The normal data storing region 12 and the parity storing region 14 may have the same structure. For example, when the burst length of the segment data is 8, the parity bits may be stored on the basis of an 8-parity-bit unit.

Each of the normal data storing region 12 and the parity storing region 14 may include a plurality of cell matrices MAT that are disposed in a row direction and a column direction. Also, a plurality of local data lines LIOi<0:7> may be disposed between the cell matrices, and a plurality of segment data lines SIO<0:7> may be disposed to intersect with the local data lines LIOi<0:7>. The local data lines LIOi<0:7> may be coupled to a DQ pad through an input/output sense amplifier IOSA. Herein, in the normal data storing region 12, a predetermined number of cell matrices MAT sharing the same local data lines LIOi<0:7> may form one cell matrix array 12U. Also, in the parity storing region 14, a predetermined number of cell matrices MAT sharing the same local data lines LIOE<0:7> may form one cell matrix array 14U. Meanwhile, although the drawing shows the local data lines LIOi<0:7> and the segment data lines SIO<0:7>, a local data line pair LIOI<0:7> and LIOBi<0:7> and a segment data line pair SIO<0:7> and SIOB<0:7> may be actually disposed.

In the above-described structure, in the normal data storing region 12, 8 bit line pairs BL and BLB (not shown) may be selected based on a one-time column selection signal CYi, and 8 data may be transferred from the 8 bit line pairs BL and BLB to the local data lines LIOi<0:7> through the segment data lines SIO<0:7>. The 8 data transferred to the local data lines LIOi<0:7> may be amplified in the input/output sense amplifier IOSA and, eventually, aligned to a predetermined number of data and outputted through the DQ pad.

Likewise, in the parity storing region 14, 8 bit line pairs BL and BLB (not shown) may be selected based on a one-time column selection signal CYi, and 8 parity bits may be transferred to the local data lines LIOE<0:7> through the segment data lines SIO<0:7>. The 8 parity bits transferred to the local data lines LIOE<0:7> may be, eventually, transferred to the ECC device (not shown) through additional lines ECCP<0:7> that are dedicated to the transfer of the parity bits, which will be referred to as dedicated lines ECCP<0:7>, hereafter. Subsequently, the ECC device may perform an ECC operation of detecting and correcting an error of a defective memory cell by using the parity bits.

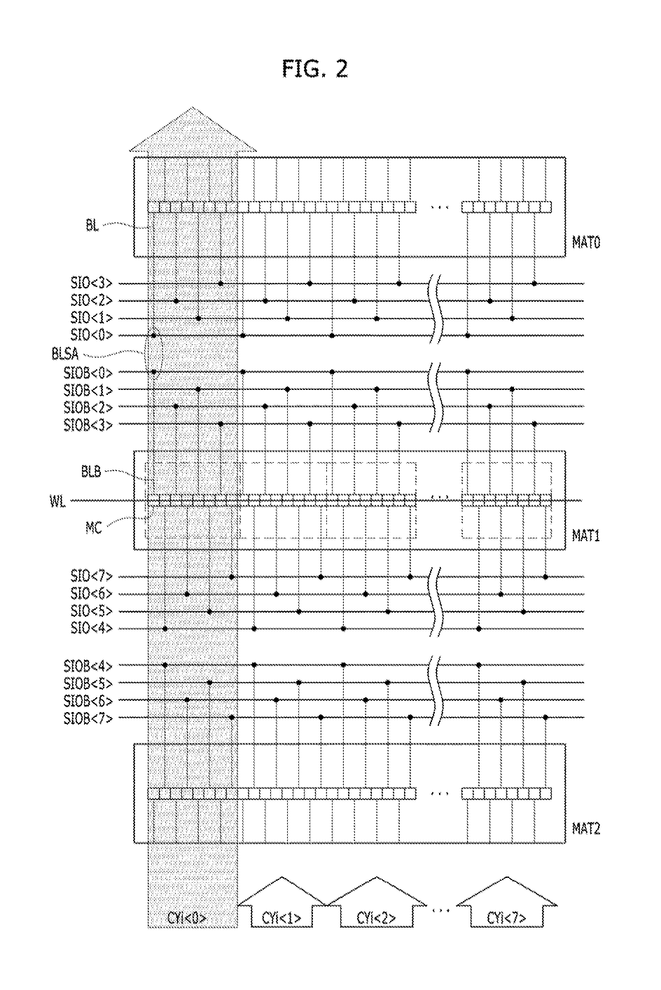

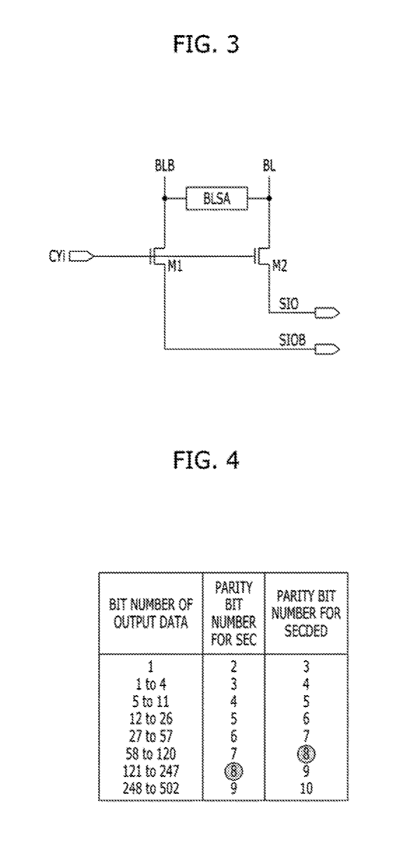

FIG. 2 is a schematic diagram illustrating a coupling between a segment data line and a cell matrix of the parity storing region 14 shown in FIG. 1. FIG. 3 is a schematic diagram illustrating a coupling between a bit line and a segment data line according to a column selection signal CYi shown in FIG. 2.

Referring to FIG. 2, a coupling between a plurality of cell matrices MAT0 to MAT2 and a segment data line pair SIO<0:7> and SIOB<0:7> is shown.

After a word line WL is enabled, when one (e.g., a first column selection signal CYi<0>) among a plurality of column selection signals CYi is selected, 8 data may be transferred from the memory cells that are disposed in a cell matrix (e.g., a second cell matrix MAT1) corresponding to the enabled word lien WL to a bit line pair BL and BLB. The 8 data that are transferred to the bit line pair BL and BLB may be sensed and amplified in a bit line sense amplifier BLSA and transferred to the segment data line pair SIO<0:7> and SIOB<0:7>, respectively.

Referring to FIG. 3, the bit line sense amplifier BLSA may sense and amplify the data that is transferred to the bit line pair BL and BLB and transfer the sensed and amplified data to the segment data line pair SIO and SIOB through switches (e.g., transistors M1 and M2) that are turned on when the corresponding column selection signal CYi is enabled.

FIG. 4 is a table showing the number of parity bits that are required for an error correction code (ECC) operation according to the number of bits of an output data.

Referring to FIG. 4, the table shows the number of parity bits that are required for an ECC operation that is performed based on a single error correction (SEC) code and a single error correction double error detection (SECDED) code. Herein, an output data may be defined as a data that is finally outputted to the DQ pad through a local data line and a global data line.

As shown in FIG. 4, diverse numbers of parity bits may be required according to the number of bits of the output data. For example, when the number of bits of the output data is 64, the number of the parity bits that are needed for an ECC operation based on the SEC code may be 7, and the number of the parity bits that are needed for an ECC operation based on the SECDED code may be 8.

As described above, the number of the parity bits that are needed for an ECC operation may be different according to the code based on which the ECC operation is performed. But since the normal data storing region 12 and the parity storing region 14 are realized to include the bit line sense amplifier BLSA of the same structure, the number of the parity bits may be set up based on the burst length of the segment data. In other words, when the segment data has a burst length corresponding to a multiple of 8 at a time based on the 8IO/1CYi, 8 parity bits may become the smallest unit and the number of the parity bits may be increased on the basis of a multiple of 8. Therefore, it is required to develop a scheme capable of supporting a case where the number of the parity bits that are required for an ECC operation is not a multiple of the burst length of the segment data, for example, a case where the burst length is 8 and the number of the required parity bits is 6, 7, and 9.

Hereafter, a scheme capable of supporting diverse number of parity bits regardless of the burst length of a segment data is described in accordance with an embodiment of the present invention with reference to the accompanying drawings.

First of all, a case of outputting less parity bits than the burst length of a segment data is described. As an example, for illustrative purposes only, a case where 6 parity bits are outputted when the burst length of the segment data is 8 is taken as an example and described.

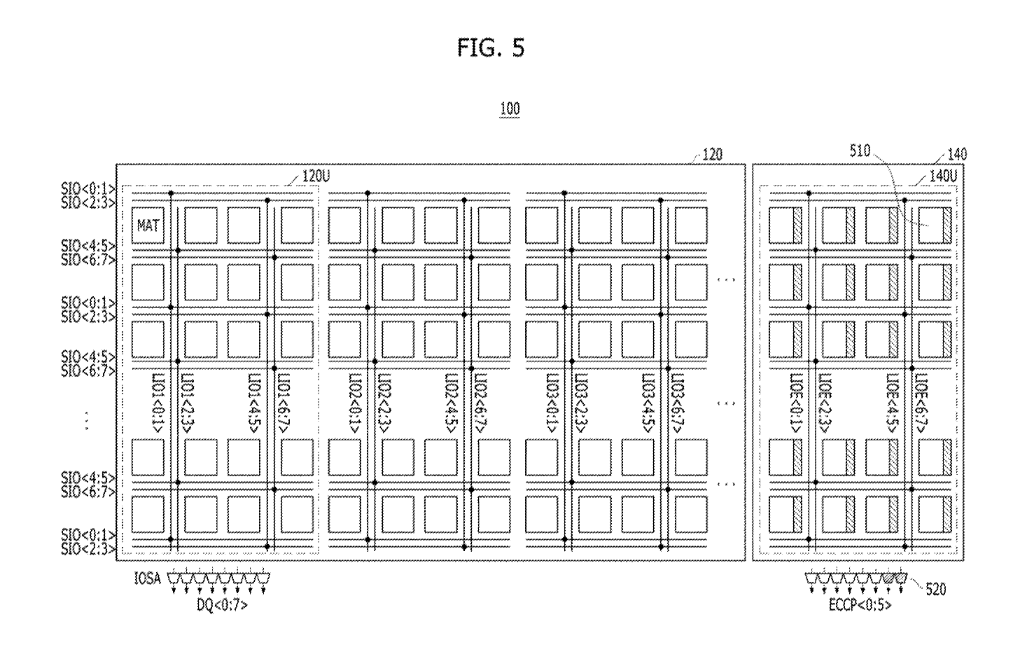

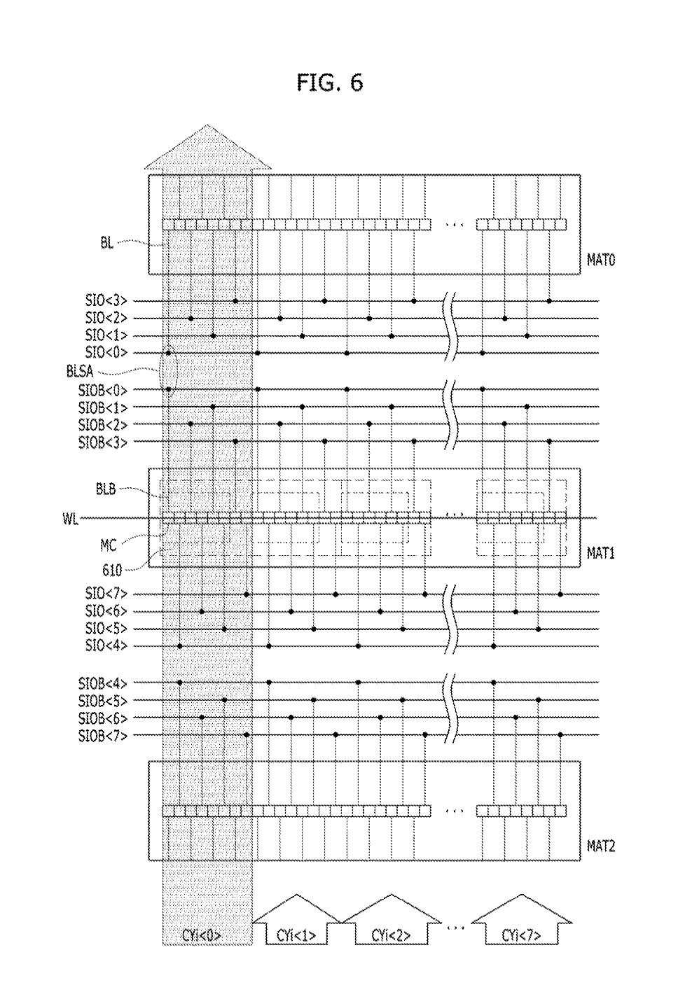

FIG. 5 is a memory bank architecture in accordance with a first embodiment of the present invention. FIG. 6 illustrates a coupling between a segment data line and a cell matrix MAT of a parity storing region 140 shown in FIG. 5.

Referring to FIG. 5, a memory bank 100 may include a normal data storing region 120 for storing normal cell data and a parity storing region 140 for storing parity bits. Each of the normal data storing region 120 and the parity storing region 140 may include a plurality of cell matrices MAT that are disposed in a row direction and a column direction. Herein, in the normal data storing region 120, a predetermined number of cell matrices MAT sharing the same local data lines LIOi<0:7> may form one cell matrix array 120U. Also, in the parity storing region 140, a predetermined number of cell matrices MAT sharing the same local data lines LIOE<0:7> may form one cell matrix array 140U. Although FIG. 5 shows that the parity storing region 140 includes one cell matrix array 140U, the concept and spirit of the present invention are not limited to it. The parity storing region 140 may include a plurality of cell matrix arrays as may be needed.

Although not illustrated in the drawing, each of the cell matrices MAT may include a plurality of memory cells (not shown) that are positioned at the cross points between a plurality of word lines WL (not shown) and a plurality of bit lines BL (not shown). The bit lines BL may be positioned to intersect with a plurality of segment data lines SIO<0:7>. As shown in FIG. 5, the segment data lines SIO<0:7> may be positioned between the cell matrices MAT. The local data lines LIOi<0:7> may be positioned to intersect with the segment data lines SIO<0:7>. The local data lines LIOi<0:7> may be coupled to a DQ pad through an input/output sense amplifier IOSA. Meanwhile, although the drawing shows the local data lines LIO<0:7> and the segment data lines SIO<0:7>, a local data line pair IOi<0:7> and LIOBi<0:7> and a segment data line pair SIO<0:7> and SIOB<0:7> may be actually disposed.

In accordance with the first embodiment of the present invention, each of the cell matrices MAT of the normal data storing region 120 may output 8 normal cell data in response to one among a plurality of column selection signals CYi<0:7> (e.g., 8 column selection signals CYi<0:7>). Each of the cell matrices MAT of the parity storing region 140 may output 6 parity bits in response to one among a plurality of column selection signals CYi<0:7> (510). In other words, whereas each of the cell matrices MAT of the normal data storing region 120 may output 8 normal data in response to one assigned column selection signal, each of the cell matrices MAT of the parity storing region 140 may output 6 parity bits.

For example, in the normal data storing region 120, 8 data may be transferred from a bit line pair BL and BLB to the local data lines LIOi<0:7> through the segment data lines SIO<0:7>. The 8 data transferred to the local data lines LIOi<0:7> may be amplified in the input/output sense amplifier IOSA and, finally, outputted through the DQ pad.

Conversely, referring to FIG. 6, in the parity storing region 140, when a word line WL is enabled and one (e.g., a first column selection signal CYi<0>) among the column selection signals CYi is selected, 8 data may be transferred from the memory cells that are positioned in a cell matrix (e.g., a second cell matrix MAT1) corresponding to the enabled word line WL to the bit line pair BL and BLB. The 8 data transferred to the bit line pair BL and BLB may be sensed and amplified in a bit line sense amplifier BLSA and transferred to a segment data line pair SIO<0:7> and SIOB<0:7>, respectively. Herein, according to the first embodiment of the present invention, the parity storing region 140 may transfer 6 data among 8 data as parity bits in response to one assigned column selection signal (610). In short, referring to FIG. 3, only 6 transistor pairs M1 and M2 may be turned on in response to the column selection signal CYi to transfer only 6 data among the 8 data transferred to the bit line pair BL and BLB to the segment data line pair SIO<0:7> and SIOB<0:7>. The 6 parity bits that are transferred to the segment data line pair SIO<0:7> and SIOB<0:7> may be transferred to the local data lines LIOE<0:7> shown in FIG. 5. The 6 parity bits that are transferred to the local data lines LIOE<0:7> may be eventually transferred to an ECC device (not shown) through dedicated lines ECCP<0:5> (520). Subsequently, the ECC device may perform an ECC operation of detecting and correcting an error of a defective memory cell by using the parity bits.

According to the first embodiment of the present invention described above, two data that are transferred to the bit line pair BL and BLB in the parity storing region 140 are not used and abandoned. In this case, since the normal data storing region 120 and the parity storing region 140 have continuity in their layout patterns, it is advantageous in terms of simple fabrication process, easy management of defects after a test, and quick defective cell screening. However, since the area is wastefully consumed for the unused bit line pair BL and BLB, it is disadvantageous in terms of a net die. For example, as shown in the shaded portion of FIG. 5, the wasteful consumption of the area may reach 2/8 (which is approximately 25%) of each cell matrix.

Hereafter, a case of outputting less parity bits than the burst length (e.g., 8) of a segment data while minimizing the wasteful consumption of the area is described.

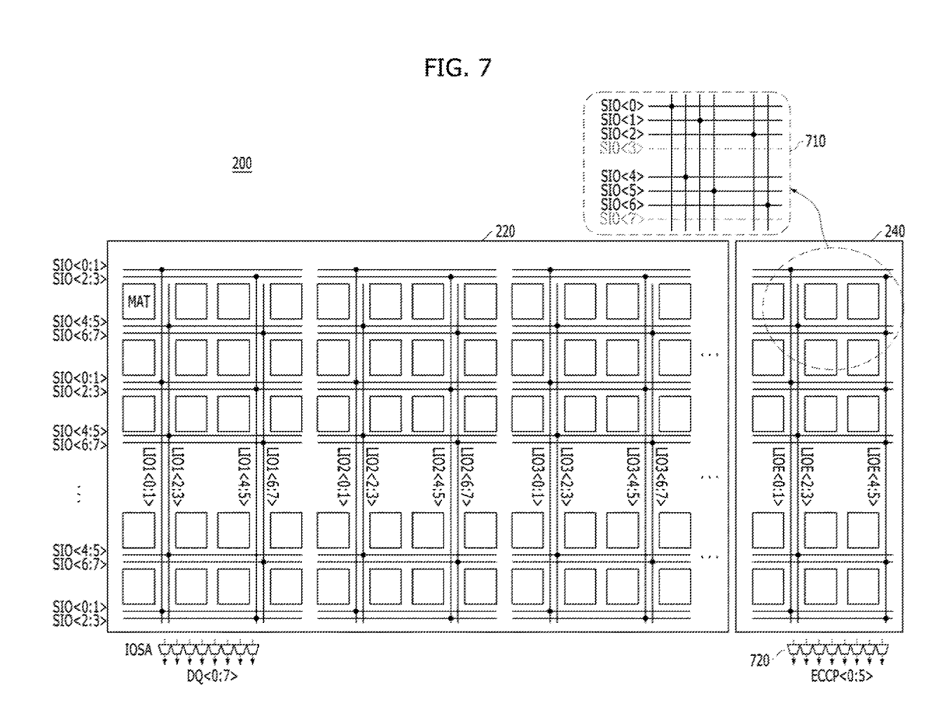

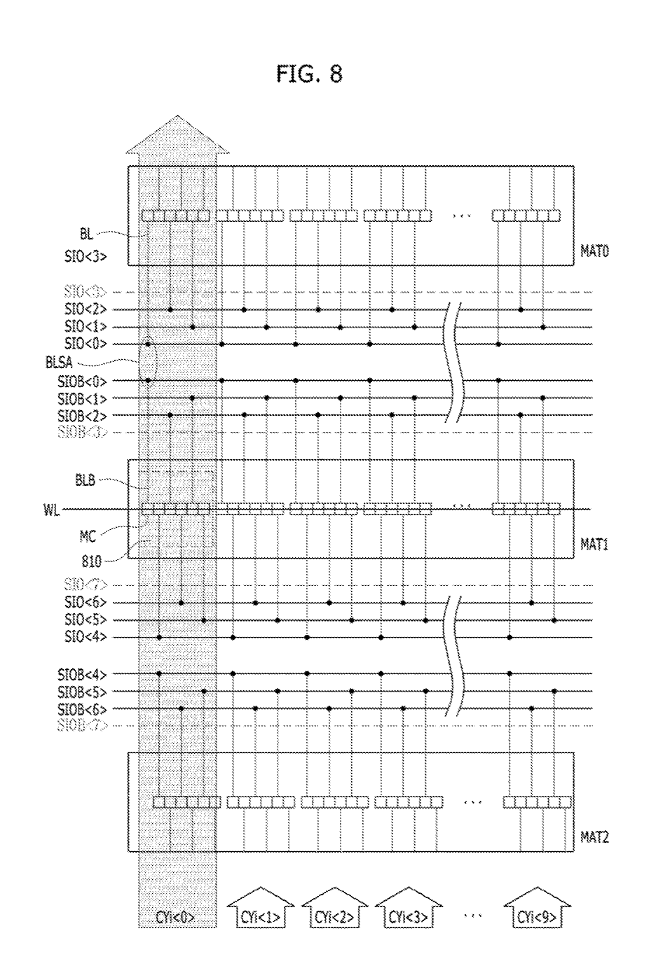

FIG. 7 is a memory bank architecture in accordance with a second embodiment of the present invention. FIG. 8 illustrates a coupling between a segment data line and a cell matrix MAT of a parity storing region 240 shown in FIG. 7.

Referring to FIG. 7, a memory bank 200 may include a normal data storing region 220 for storing normal cell data and a parity storing region 240 for storing parity bits. Each of the normal data storing region 220 and the parity storing region 240 may include a plurality of cell matrices MAT that are disposed in a row direction and a column direction.

In accordance with the second embodiment of the present invention, each of the cell matrices MAT of the normal data storing region 220 may output 8 normal cell data in response to one among a plurality of column selection signals CYi<0:7> (e.g., 8 column selection signals CYi<0:7>). Each of the cell matrices MAT of the parity storing region 240 may output 6 parity bits in response to one among a plurality of column selection signals CYi<0:7> (710). In other words, whereas each of the cell matrices MAT of the normal data storing region 220 may output 8 normal data in response to one assigned column selection signal, each of the cell matrices MAT of the parity storing region 240 may output 6 parity bits.

For example, in the normal data storing region 220, 8 data may be transferred from a bit line pair BL and BLB to the local data lines LIOi<0:7> through the segment data lines SIO<0:7>. The 8 data transferred to the local data lines LIOi<0:7> may be amplified in the input/output sense amplifier IOSA and, finally, outputted through the DQ pad.

Conversely, referring to FIG. 8, in the parity storing region 240, when a word line WL is enabled and one (e.g., a first column selection signal CYi<0>) among the column selection signals CYi is selected, 6 data may be transferred from the memory cells that are positioned in a cell matrix (e.g., a second cell matrix MAT1) corresponding to the enabled word line WL to the bit line pair BL and BLB. The 6 data transferred to the bit line pair BL and BLB may be sensed and amplified in a bit line sense amplifier BLSA and transferred to a segment data line pair SIO<0:2, 4:6> and SIOB<0:2, 4:6>, respectively (810). Herein, according to the second embodiment of the present invention, whereas 8 segment data line pairs SIO<0:7> and SIOB<0:7> are disposed in the normal data storing region 220, only 6 segment data line pairs SIO<0:2, 4:6> and SIOB<0:2, 4:6> are disposed in the parity storing region 240. Therefore, the 6 data transferred to the bit line pair BL and BLB in response to one assigned column selection signal may be all transferred to the 6 segment data line pairs SIO<0:2, 4:6> and SIOB<0:2, 4:6>. The 6 parity bits that are transferred to the segment data line pairs SIO<0:2, 4:6> and SIOB<0:2, 4:6> may be transferred to the local data lines LIOE<0:5> shown in FIG. 7. The 6 parity bits that are transferred to the local data lines LIOE<0:5> may be eventually transferred to an ECC device (not shown) through dedicated lines ECCP<0:5> (720).

According to the second embodiment of the present invention described above, 8 bit line pairs may be selected for each cell matrix in response to a one-time column selection signal CYi based on the 8IO/1CYi and 8 data may be outputted in the normal data storing region 220, and 6 bit line pairs may be selected for each cell matrix in response to a one-time column selection signal CYi based on the 6IO/1CYi and 6 data may be outputted in the parity storing region 240. Therefore, as illustrated in FIG. 7, it is possible to store and output the same parity bits with a smaller area than the area of the parity storing region 140 shown in FIG. 5.

Hereafter, a case of outputting more parity bits than the burst length of a segment data is described. As an example, for illustrative purposes only, a case where 9 parity bits are outputted when the burst length of a segment data is 8 is taken as an example and described.

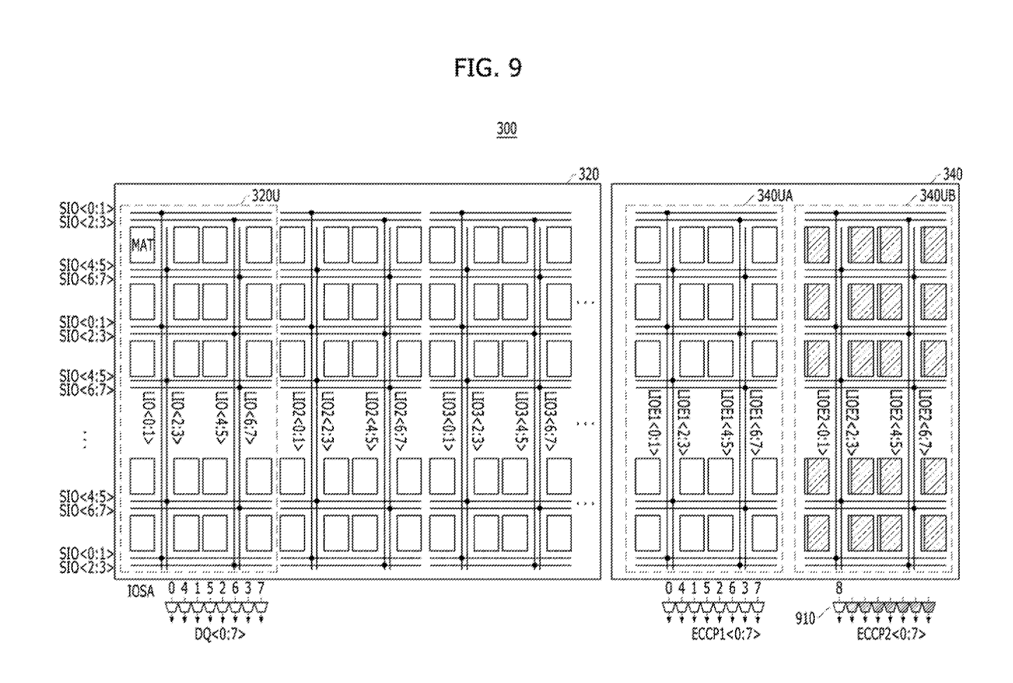

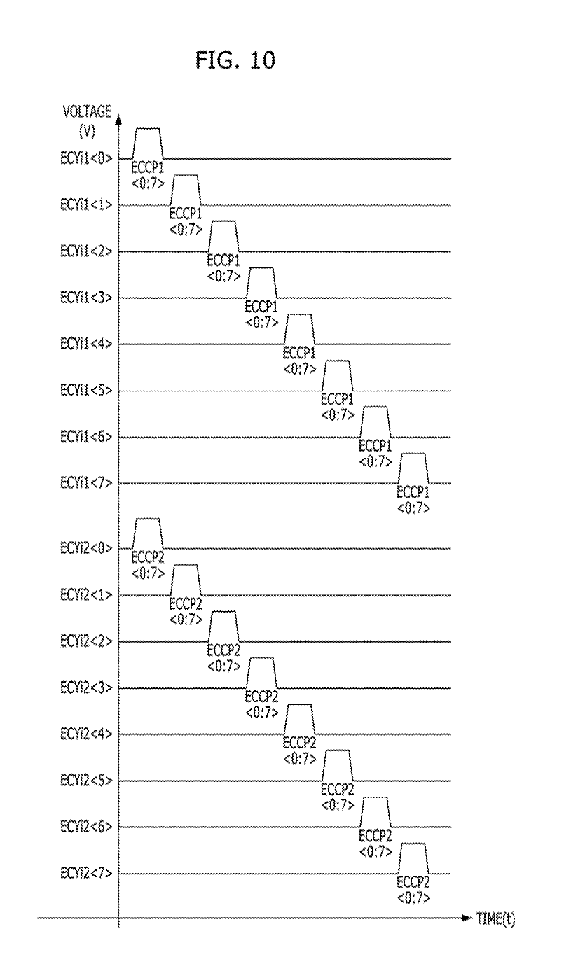

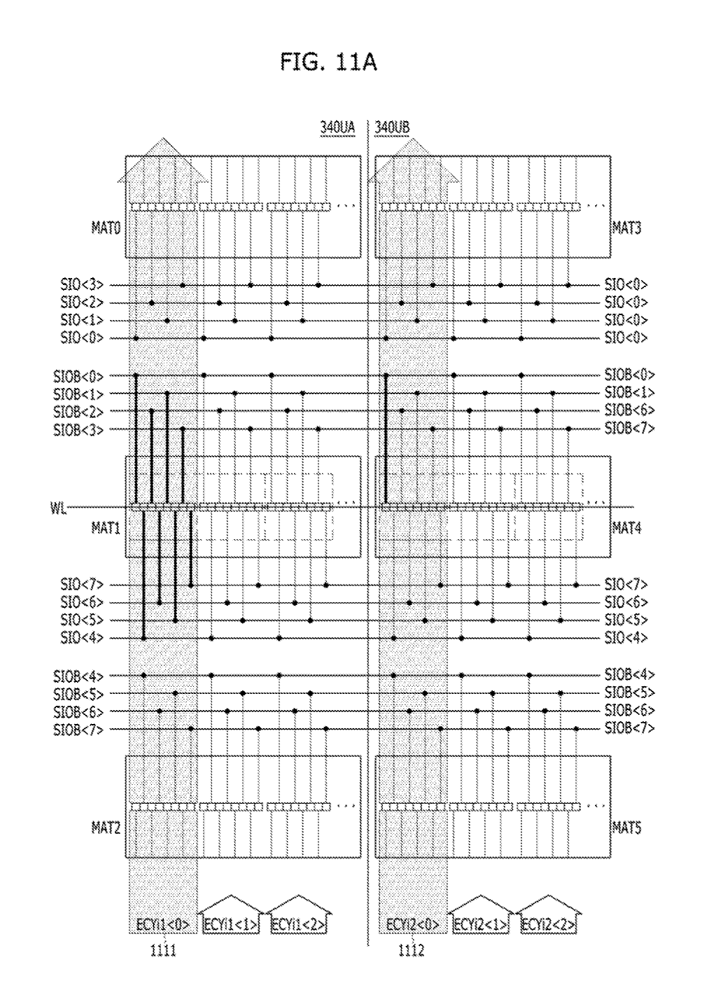

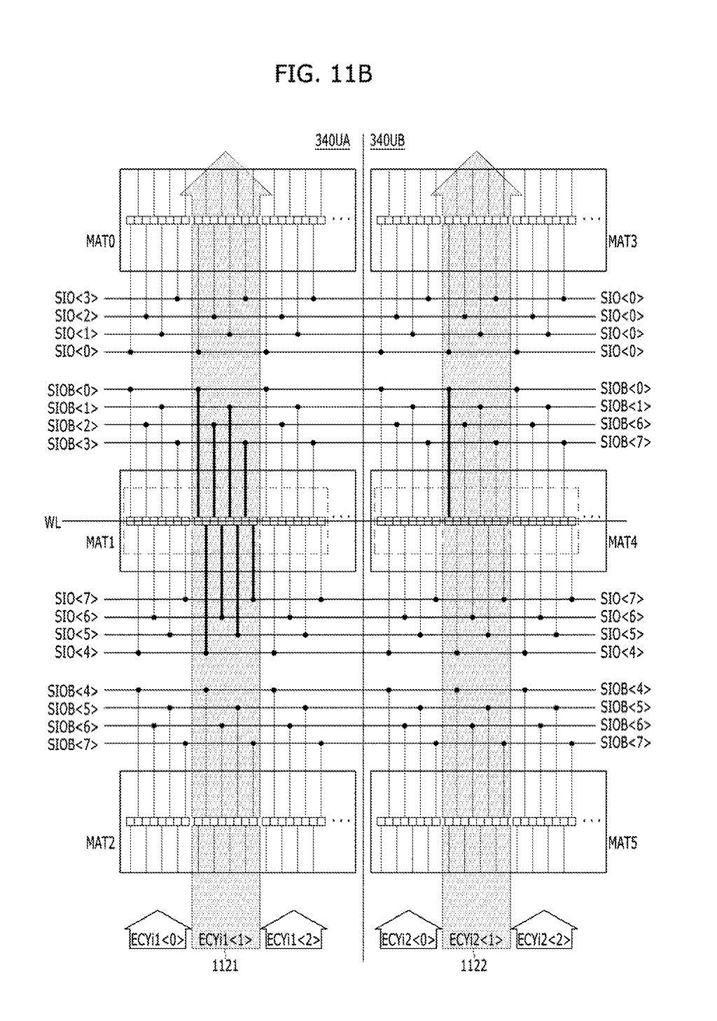

FIG. 9 is a memory bank architecture in accordance with a third embodiment of the present invention. FIG. 10 is a timing diagram illustrating a column selection signal shown in FIG. 9. FIGS. 11A and 11B illustrate a coupling between a segment data line and a cell matrix of a parity storing region 340 shown in FIG. 9.

Referring to FIG. 9, a memory bank 300 may include a normal data storing region 320 for storing normal cell data and a parity storing region 340 for storing parity bits. Each of the normal data storing region 320 and the parity storing region 340 may include a plurality of cell matrices MAT that are disposed in a row direction and a column direction. Herein, in the normal data storing region 320, a predetermined number of cell matrices MAT sharing the same local data lines LIO<0:7> may form one cell matrix array 320U. Also, in the parity storing region 340, a predetermined number of cell matrices MAT sharing the same local data lines LIOEi<0:7> may form one cell matrix array 340UA or 340UB. Herein, when more parity bits than the burst length of a segment data are outputted, the parity storing region 340 may include at least two cell matrix arrays 340UA and 340UB. For example, the cell matrices MAT of a first cell matrix array 340UA may share first local data lines LIOE1<0:7>, and the cell matrices MAT of a second cell matrix array 340UB may share second local data lines LIOE2<0:7>.

In accordance with the third embodiment of the present invention, each of the cell matrices MAT of the normal data storing region 320 may output 8 normal cell data in response to one among a plurality of column selection signals CYi<0:7> (e.g., 8 column selection signals CYi<0:7>). Each of the cell matrices MAT of the parity storing region 340 may output 9 parity bits in response to at least two column selection signals among a plurality of column selection signals CYi<0:7> (910). In other words, whereas each of the cell matrices MAT of the normal data storing region 320 may output 8 normal data in response to one assigned column selection signal, each of the cell matrices MAT of the parity storing region 340 may output a different number of parity bits.

Hereafter, as an example, for illustrative purposes only, it is defined that the column selection signals CYi<0:7> used in each of the cell matrix arrays 340UA and 340UB of the parity storing region 340 include a first column selection signal ECYi1<0:7> and a second column selection signal ECYi2<0:7>. Referring to FIG. 10, in accordance with the third embodiment of the present invention, each bit signal of the first column selection signal ECYi1<0:7> and the second column selection signal ECYi2<0:7> may be enabled simultaneously. For example, third bit signals ECYi1<2> and ECYi2<2> of the first column selection signal ECYi1<0:7> and the second column selection signal ECYi2<0:7> may be enabled simultaneously. Therefore, 16 parity bits may be outputted through first dedicated lines ECCP1<0:7> and second dedicated lines ECCP2<0:7>.

For example, in the parity storing region 340, after a word line WL is enabled, the bit signals of the first column selection signal ECYi1<0:7> and the second column selection signal ECYi2<0:7> may be simultaneously enabled.

Referring to FIG. 11A, first bit signals ECYi1<0> and ECYi2<0> of the first column selection signal ECYi1<0:7> and the second column selection signal ECYi2<0:7> may be enabled (1111, 1112). Therefore, 8 data may be transferred from the memory cells that are positioned in the cell matrices (e.g., a second cell matrix MAT1 and a fifth cell matrix MAT4) corresponding to the enabled word line WL to the bit line pair BL and BLB. The 8 data transferred to the bit line pair BL and BLB may be sensed and amplified in a bit line sense amplifier BLSA and transferred to the segment data line pair SIO<0:7> and SIOB<0:7>, respectively. The 8 parity bits may be transferred to each of the segment data line pair SIO<0:7> and SIOB<0:7> through the first local data lines LIOE1<0:7> and the second local data lines LIOE2<0:7> of FIG. 9, and eventually transferred to an ECC device (not shown) through dedicated lines, which include first dedicated lines ECCP1<0:7> and second dedicated lines ECCP2<0:7> (910). Herein, one bit among the parity bits that are transferred from the fifth cell matrix MAT4 disposed in the second cell matrix array 340UB through the second dedicated lines ECCP2<0:7> may have a valid value. For example, only the parity bit transferred from the fifth cell matrix MAT4 through a first segment data line pair SIO<0> and SIOB<0> may have a valid value. Therefore, the ECC device may perform an ECC operation of detecting and correcting an error of a detective memory cell by using the 9 parity bits that are transferred through the first dedicated lines ECCP1<0:7> and the second dedicated lines ECCP2<0:7>.

Subsequently, referring to FIG. 11B, second bit signals ECYi1<1> and ECYi2<1> of the first column selection signal ECYi1<0:7> and the second column selection signal ECYi2<0:7> may be enabled (1121, 1122). Likewise, the 8 data may be transferred from the memory cells that are positioned in the second cell matrix MAT1 and the fifth cell matrix MAT4 through the first local data lines LIOE1<0:7> and the second local data lines LIOE2<0:7> of FIG. 9, and eventually transferred to the ECC device through the additional lines, which include the first dedicated lines ECCP1<0:7> and the second dedicated lines ECCP2<0:7> (910). Similarly, only the parity bit transferred through the first segment data line pair SIO<0> and SIOB<0> among the parity bits transferred from the fifth cell matrix MAT4 through the second dedicated lines ECCP2<0:7> may have a valid value. Therefore, the ECC device may perform an ECC operation of detecting and correcting an error of a detective memory cell by using the 9 parity bits that are transferred through the first dedicated lines ECCP1<0:7> and the second dedicated lines ECCP2<0:7>.

As described above, in accordance with the third embodiment of the present invention, data of a multiple of 8 may be read out in response to at least two column selection signals that are enabled simultaneously in the parity storing region 340, and among the data that are read out, only valid bits may be used as the parity bits. For example, among 8 data that are transferred through the second dedicated lines ECCP2<0:7>, 7 data may not be used and abandoned. Therefore, as shown in the shaded portion (910) of FIG. 9, in case of the second cell matrix array 340UB, the wasteful consumption of the area may reach ⅞ (which is approximately 87.5%) of each cell matrix.

Hereafter, a case of outputting more parity bits (e.g., 9) than the burst length (e.g., 8) of a segment data while minimizing the wasteful consumption of the area is described.

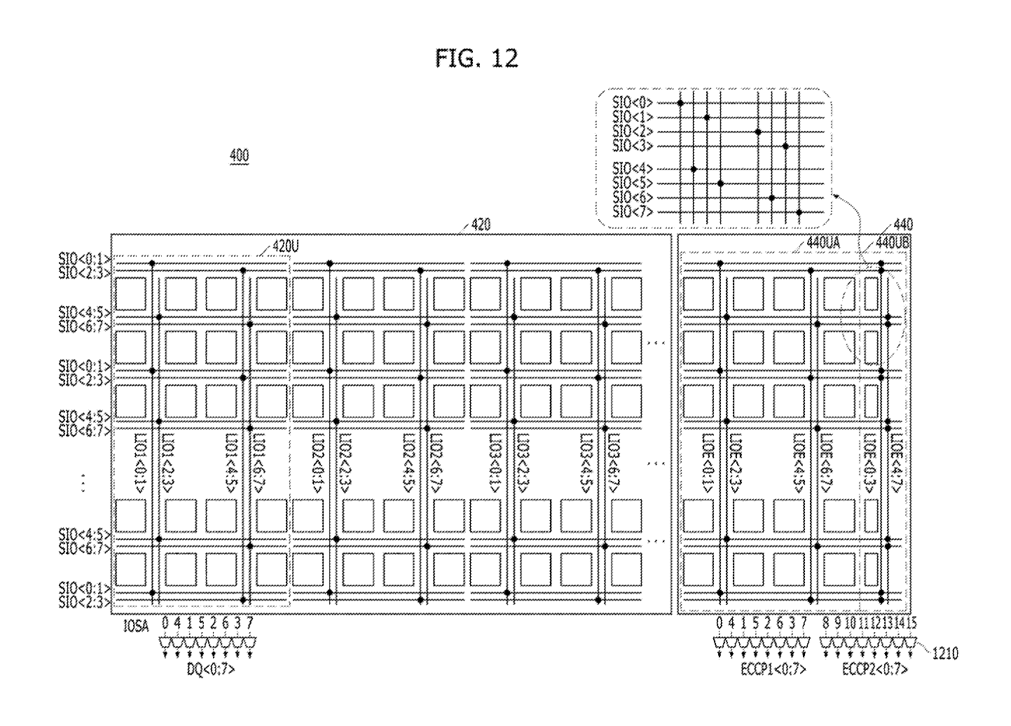

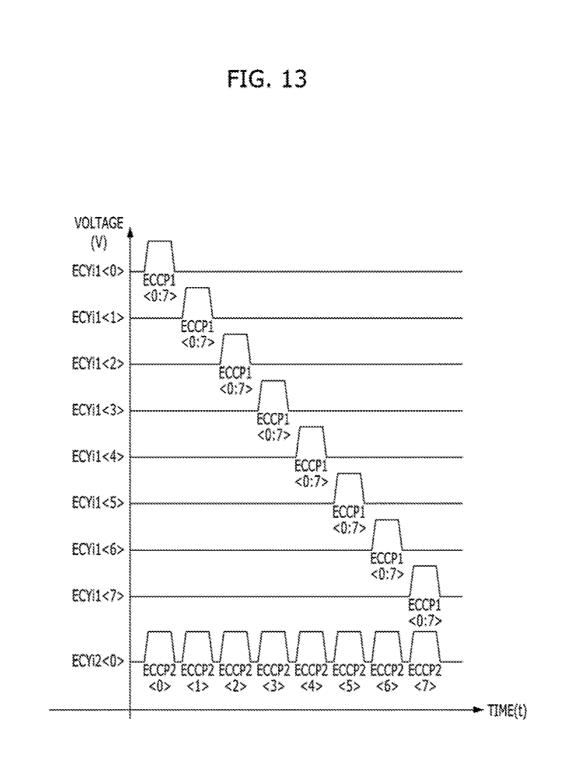

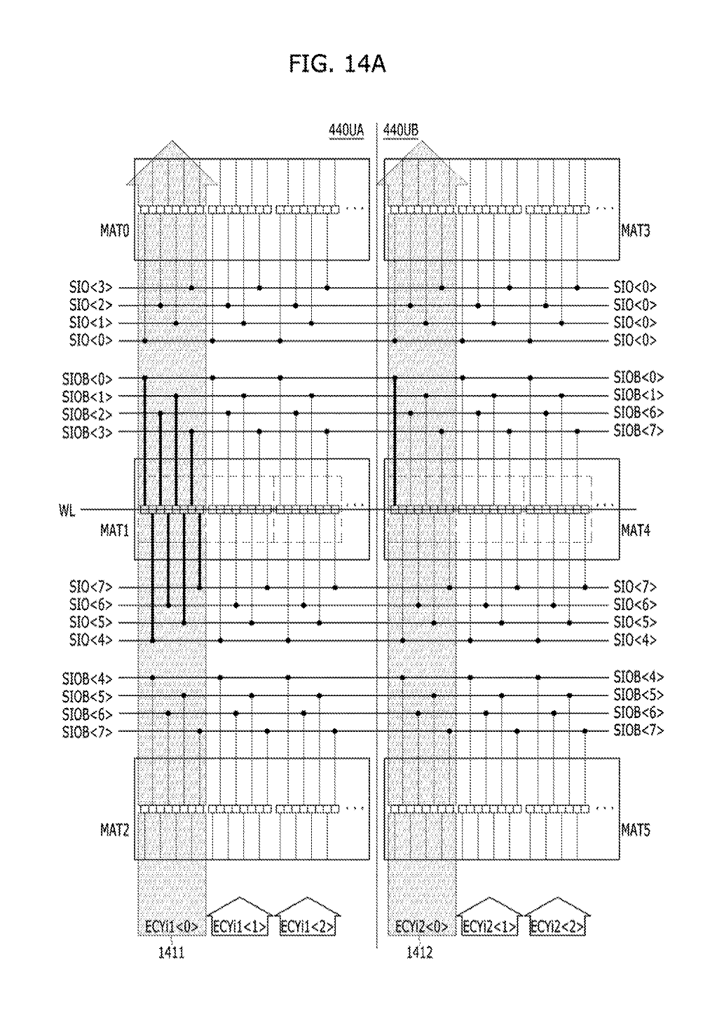

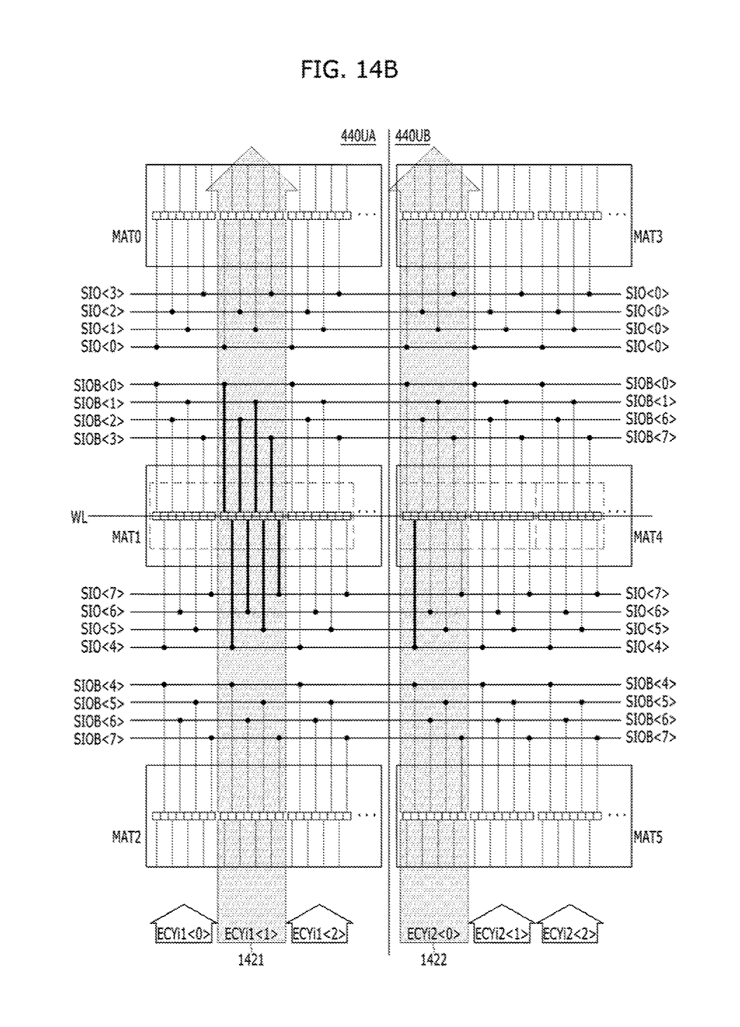

FIG. 12 is a memory bank architecture in accordance with a fourth embodiment of the present invention. FIG. 13 is a timing diagram illustrating a column selection signal shown in FIG. 12. FIGS. 14A and 14B illustrate a coupling between a segment data line and a cell matrix MAT of a parity storing region 440 shown in FIG. 12.

Referring to FIG. 12, a memory bank 400 may include a normal data storing region 420 for storing normal cell data and a parity storing region 440 for storing parity bits. In the normal data storing region 420, a predetermined number of cell matrices MAT sharing the same local data lines LIOi<0:7> may form one cell matrix array 420U. Also, in the parity storing region 440, a predetermined number of cell matrices MAT sharing the same local data lines LIOEi<0:7> may form one cell matrix array 440UA or 440UB. Herein, when more parity bits than the burst length of a segment data are outputted, the parity storing region 440 may include at least two cell matrix arrays 440UA and 440UB. For example, the cell matrices MAT of a first cell matrix array 440UA may share first local data lines LIOE1<0:7>, and the cell matrices MAT of a second cell matrix array 440UB may share second local data lines LIOE2<0:7>.

Referring to FIG. 13, in accordance with the fourth embodiment of the present invention, the bit signals of the first column selection signal ECYi1<0:7> and a first bit signal ECYi2<0> of the second column selection signal ECYi2<0:7> may be enabled simultaneously. Therefore, when 8 parity bits are outputted through the first dedicated lines ECCP1<0:7>, one parity bit may be outputted through one dedicated line among the second dedicated lines ECCP2<0:7> may be outputted (1210 of FIG. 12). Eventually, 9 parity bits may be outputted.

For example, in the parity storing region 440, after a word line WL is enabled, the bit signals of the first column selection signal ECYi1<0:7> and a particular bit signal (e.g., a first bit signal ECYi2<0>) of the second column selection signal ECYi2<0:7> may be simultaneously enabled.

Referring to FIG. 14A, first bit signals ECYi1<0> and ECYi2<0> of the first column selection signal ECYi1<0:7> and the second column selection signal ECYi2<0:7> may be enabled (1411, 1412). Therefore, 8 data may be transferred from the memory cells that are positioned in a second cell matrix MAT1 and a fifth cell matrix MAT4 through the first local data lines LIOE1<0:7> and the second local data lines LIOE2<0:7> of FIG. 12 and may be eventually transferred to an ECC device through one line (i.e., ECCP2<0>) among the first dedicated lines ECCP1<0:7> and the second dedicated lines ECCP2<0:7>. Therefore, the ECC device may perform an ECC operation of detecting and correcting an error of a detective memory cell by using the 9 parity bits that are transferred through the first dedicated lines ECCP1<0:7> and the second dedicated line ECCP2<0>.

Subsequently, referring to FIG. 14B, when a second bit signal ECYi1<1> of the first column selection signal ECYi1<0:7> is enabled, a first bit signal ECYi2<0> of the second column selection signal ECYi2<0:7> may be enabled again (1421, 1422). Thus, 8 data may be transferred from the memory cells that are positioned in the second cell matrix MAT1 and the fifth cell matrix MAT4 through the first local data lines LIOE1<0:7> and the second local data lines LIOE2<0:7> of FIG. 12 and may be eventually transferred to the ECC device through one line (i.e., ECCP2<1>) among the first dedicated lines ECCP1<0:7> and the second dedicated lines ECCP2<0:7>. Therefore, the ECC device may perform an ECC operation of detecting and correcting an error of a detective memory cell by using the 9 parity bits.

As described above, in accordance with the fourth embodiment of the present invention, data of a multiple of 8 may be read out in response to at least two column selection signals that are enabled simultaneously in the parity storing region 440, and among the data that are read out, only valid bits may be used as the parity bits. Herein, when the bit signals of the first column selection signal ECYi1<0:7> are sequentially enabled, a particular bit signal of the second column selection signal ECYi2<0:7> may be repeatedly enabled. Therefore, when 9 parity bits are required, the first and second cell matrix arrays 340UA and 340UB of the same memory cell number (which is the same area) are required in accordance with the third embodiment of the present invention. However, in accordance with the fourth embodiment of the present invention, the second cell matrix array 440UB having as many memory cells (i.e., ⅛ of the area) as an eighth (⅛, which is 1/the first column selection signal ECYi1<0:7>) of the first cell matrix array 440UA is required. Consequently, N data for each cell matrix may be acquired through a segment data line according to each bit signal of a column selection signal CYi<0:J−1> (which means that the burst length of a segment data is N). When (N+K) parity bits (where K is a positive integer smaller than N) are required, an area twice as wide as the area for storing N parity bits is needed in accordance with the third embodiment of the present invention. However, in accordance with the fourth embodiment of the present invention, only an area corresponding to (1+K/J) times is needed. Therefore, in the fourth embodiment of the present invention, it is possible to decrease the area of the second cell matrix array 440UB and minimize the whole bank region by compressing the parity bits corresponding to K among (N+K).

According to the embodiments of the present invention, when parity bits used in an ECC operation are stored in a memory array region, the number of the parity bits may be set up in a semiconductor memory device regardless of the burst length of a segment data that is outputted from the memory array region through a segment data line. Therefore, it is possible to support diverse number of parity bits.

Also, according to the embodiments of the present invention, it is possible to minimize the increase in the area of a semiconductor memory device that may occur when the number of parity bits used for an ECC operation is different from the burst length of a segment data.

While the present invention has been described with respect to specific embodiments, it will be apparent to those skilled in the art that various changes and modifications may be made without departing from the spirit and scope of the invention as defined in the following claims.

What is claimed is:

1. A semiconductor memory device comprising:
a normal data storing region suitable for storing normal cell data and outputting N normal cell data to a first local data line in response to one of a plurality of column selection signals; and
a parity storing region suitable for storing parity bits and outputting M parity bits to a second local data line in response to at least one of the plurality of the column selection signals, N and M being positive integers,
wherein, when M is smaller than N, the parity storing region outputs the M parity bits in response to one of the plurality of the column selection signals, and
when M is greater than N, the parity storing region outputs the M parity bits in response to at least two column selection signals that are enabled simultaneously among the plurality of the column selection signals.

2. The semiconductor memory device of claim 1, wherein when M is (N+K), K being a positive integer smaller than N, and a first column selection signal and a second column selection signal are simultaneously enabled,
the parity storing region outputs N parity bits in response to the first column selection signal, and outputs K parity bits in response to the second column selection signal.

3. The semiconductor memory device of claim 1, wherein the plurality of the column selection signals include
X first column selection signals, and
a second column selection signal that is simultaneously enabled when the first column selection signals are individually enabled.

4. The semiconductor memory device of claim 3, wherein the parity storing region includes:
a first storing region suitable for outputting the N parity bits in response to one of the X first column selection signals; and
a second storing region suitable for outputting the K parity bits in response to the second column selection signal.

5. The semiconductor memory device of claim 1, wherein the normal cell data are outputted to a data pad through the first local data line.

6. The semiconductor memory device of claim 5, wherein the parity bits are outputted to a dedicated line which is different from the data pad through the second local data line.

7. The semiconductor memory device of claim 1, wherein each of the normal data storing region and the parity storing region includes:
a bit line sense amplifier suitable for sensing and amplifying a data transferred through a bit line; and
a switch suitable for outputting the sensed and amplified data through the first local data line or the second local data line in response to one of the plurality of the column selection signals.

8. A semiconductor memory device comprising:
a normal data storing region suitable for storing normal cell data and outputting N normal cell data to first segment data lines in response to one of a plurality of column selection signals, N being a positive integer; and
a parity storing region suitable for storing parity bits and outputting M parity bits to second segment data lines in response to one of the plurality of the column selection signals, M being a positive integer smaller than N,
wherein the number of the second segment data lines is smaller than the number of the first segment data lines.

9. The semiconductor memory device of claim 8, wherein the normal cell data are outputted to a data pad through the first segment data lines.

10. The semiconductor memory device of claim 9, wherein the parity bits are outputted to a dedicated line which is different from the data pad through the second segment data lines.

11. The semiconductor memory device of claim 8, wherein each of the normal data storing region and the parity storing region includes:
a bit line sense amplifier suitable for sensing and amplifying a data transferred through a bit line; and
a switch suitable for outputting the sensed and amplified data through the first segment data lines or the second segment data lines in response to one of the plurality of the column selection signals.

12. A semiconductor memory device comprising:
a normal data storing region suitable for storing normal cell data and outputting N normal cell data to a first local data line in response to one of a plurality of column selection signals, N being a positive integer; and
a parity storing region suitable for storing parity bits and outputting (N+K) parity bits to a second local data line in response to two column selection signals that are simultaneously enabled among the plurality of the column selection signals, K being a positive integer smaller than N.

13. The semiconductor memory device of claim 12, wherein the plurality of the column selection signals include
X first column selection signals, and
a second column selection signal that is simultaneously enabled whenever the first column selection signals are individually enabled.

14. The semiconductor memory device of claim 13, wherein the parity storing region includes:
a first storing region suitable for outputting the N parity bits in response to one of the first column selection signals; and
a second storing region suitable for outputting the K parity bits in response to the second column selection signal.

15. The semiconductor memory device of claim 12, wherein the normal cell data are outputted to a data pad through the first local data line.

16. The semiconductor memory device of claim 15, wherein the normal cell data are outputted to a data pad through the first local data line.

17. The semiconductor memory device of claim 12, wherein each of the normal data storing region and the parity storing region includes:
a bit line sense amplifier suitable for sensing and amplifying a data transferred through a bit line; and
a switch suitable for outputting the sensed and amplified data through the first local data line or the second local data line in response to one of the plurality of the column selection signals.
